(19) United States
(12) Patent Application Publication
(10) Pub. No.: US 2009/0140125 A1
(43) Pub. Date: Jun. 4, 2009

(54) IMAGING DEVICE

(75) Inventor: Jun Takayama, Tokyo (JP)

Correspondence Address: LUCAS & MERCANTI, LLP, 475 PARK AVENUE SOUTH, 15TH FLOOR, NEW YORK, NY, 10016, US

(73) Assignee: KONICA MINOLTA HOLDINGS, INC., Tokyo (JP)

(21) Appl. No.: 11/915,762

(22) PCT Filed: May 12, 2006
(86) PCT No.: PCT/JP2006/309541

§ 371 Date: Nov. 28, 2007

(30) Foreign Application Priority Data
Jun. 3, 2005 (JP) 2005164306

(51) Int. Cl. H01J 40/14; G01K 13/00

(52) U.S. Cl. 250/214 R; 374/142; 374/E13.001

(57) ABSTRACT

The present invention provides an imaging device where the temperature of an imaging area of the imaging device is accurately detected to perform precise temperature compensation and the imaging device can be minimized as a whole. This imaging device is characterized in that the device includes: the imaging element (5) for converting incident light into an electric signal; a signal processing chip (6) mounted by being stacked with the imaging element (5); and a temperature sensor (8) integrated into the signal processing chip (6) close to the imaging element (5) in a state where the imaging element (5) and the signal processing chip (6) are stacked.

### FIELD OF THE INVENTION

The present invention relates to an imaging device having an imaging element particularly having a temperature characteristic.

### BACKGROUND

An imaging element for photoelectric conversion to convert incident

light to an electric signal has been provided for an imaging device such as a camera unit integrated in a digital camera or an onboard camera. As the imaging element, CCD (Charging Couple Device) type image sensor or CMOS (Complementary Metal-Oxide Semiconductor) type image sensor has been widely used.

Since the CCD type image sensor and CMOS image sensor have a temperature characteristic, there has been known an imaging device that according to a temperature inside an imaging device detected by a sensor, a compensation amount of image data obtained by the image sensor is calculated and the photographed image is compensated so as to obtain an optimum image.

For example, in a Patent Document 1, there is described an imaging device where variation of an output signal due to the temperature characteristic of the imaging element is compensated in accordance with a temperature in a vicinity of a temperature sensor provided on the head sink member on which a peltiert element to cool the imaging element is carried.

Also, in a Patent document 2, there is described an imaging device where variation of an output signal due to the temperature characteristic of the imaging element is compensated in accordance with a temperature in a vicinity of the imaging element detected by a sensor which is provided in a vicinity of the imaging element inside a housing of an imaging device.

Further, in a Patent Document 3, there is described an imaging device where variation of an output signal due to the temperature characteristic of an imaging element is compensated in accordance with a temperature in a vicinity of an imaging area detected by a sensor which is provided in a in periphery of the imaging area of the imaging element.

Patent Document 1: Tokkaihei 7-038019

Patent Document 2: Tokkaihei 7-270177

Patent document 3: Tokkai 2000-162036

### DISCLOSURE OF THE INVENTION

### Problem to be Solved by the Present Invention

However, in the imaging device described in the Patent document 1, since the imaging element and the temperature sensor are configured as different members, a physical distance between them becomes large, thus an accuracy of temperature detection is deteriorated and a manufacturing cost increases due to an additional assembling process of the temperature sensor.

Also, in the imaging device described in the Patent document 2, though the temperature sensor is provided in the vicinity of the imaging element, the imaging element, the temperature sensor and an electronic circuit are configured as different members, there was a problem that an entire imaging device cannot be compact. Also, in a case where due to a layout and a shape a contact area with the imaging element cannot be large, the temperature of the imaging element was not able to detect accurately.

Also, in the imaging device described in the Patent document 3, though the temperature sensor is provided on the imaging element, since the temperature sensor is not located in the imaging area of the imaging element and located in the periphery of the imaging area, there was a problem that the temperature of the imaging area was not able to detect accurately.

An object of the present invention is to provide an imaging device where the temperature of the imaging area of the imaging element is detected accurately, precise temperature compensating is performed and the imaging device is made compact.

### Means to Solve the Problem

To solve the above problem, the invention described in claims 1 is a imaging device characterized in that the imaging device includes an imaging element to convert incident light into an electric signal; and a signal processing chip mounted and stacked with the imaging element; and a temperature sensor integrated in a signal processing chip close to the imaging element in a state where the imaging element and the signal processing chip are stacked.

According the invention described in claim 1, since the temperature sensor is integrated into the signal processing chip, components of the imaging device can be minimized in size and dimensions. Also, since output signals of the imaging element are all processed in the signal processing chip, a wiring space can be minimized. Further by integrating the temperature sensor into the signal processing chip beforehand, the manufacturing process of the imaging device can be simple compared to a case where these components are manufactured and arranged as different members. In addition, by stacking the imaging element and the signal processing chip where the temperature sensor is integrated, the components of the imaging device can be minimized and by acquiring an area where the temperature sensor and the imaging element adjacent to each other widely, the temperature of the imaging element can be detected accurately.

The invention described in claim 2 is an imaging device described in claim 1 characterized in that the imaging device includes a control section to compensate variation of an output signal of the imaging element caused by a variation of temperature based on a detected result of the temperature sensor.

According to the invention described in claim 2, using temperature data of the imaging element accurately detected by the temperature sensor integrated into the signal processing chip, a variation of the output signal of the imaging element can be compensated.

The invention described in claim 3 is the imaging device described in claim 1 and claim 2, characterized in that the imaging element includes a plurality of pixels capable of switching between linear conversion operation which converts the incident light into the electric signal linearly and log conversion operation which converts the incident light into the electric signal logarithmically in accordance with an amount of the incident light.

According to the invention described in claim 3, in the imaging device including a linear log sensor to convert the incident light logarithmically or linearly in accordance with the amount of the incident light, the variation of the output signal caused by a temperature change can be compensated based on the detected result of the temperature sensor.

The invention described in claim 4 is the imaging device described in any one of claims 1 to claim 3, characterized in that the imaging element capable of switching between a plurality of linear conversion characteristics in accordance with the amount of the incident light can compensate a fluctuation of incline of linear conversion character caused by change of the temperature and a fluctuation of the changeover point. According to the invention described in claim 4 by providing the imaging element capable of switching between the plurality of linear conversion characteristics (different inclination), the fluctuation of incline of linear conversion character caused by change of the temperature and the fluctuation of the changeover point can be compensated.

The invention described in claim 5 is the imaging device described in any one of claims 1 to claim 4, characterized in that

the temperature sensor is integrated close to a rear surface side of an imaging area of the imaging element in the state where the imaging element and the signal processing chip are stacked.

According to the invention described in claim 5, because the physical distance between the temperature sensor and the imaging area of the imaging element is small, the temperature of the imaging area can be detected accurately.

The invention described in claim 6 is the imaging device described in any one of claims 1 to claim 5, characterized in that the temperature sensor is integrated close to a vicinity of a center of the imaging area of the imaging element in the state where the imaging element and the signal processing chip are stacked.

According to the invention described in claim 6, since the temperature sensor is integrated close to the vicinity of the center of the imaging area of the imaging element, the temperature of the most desirable area to be measured within the imaging area can be detected.

The invention described in claim 7 is the imaging device described in any one of claims 1 to claim 6, characterized in that the temperature sensor is provided at an overlapping area of the imaging area of the imaging element.

According to the invention described in claim 7, since the temperature sensor is provided in the imaging area of the imaging element, accurate temperature detection can be realized without temperature detection being varied.

The invention described in claim 8 is the imaging device described in any one of claims 1 to claim 5, characterized in that a plurality of temperature sensors are integrated in the signal processing chip.

According to the invention described in claim 8, since the plurality of temperature sensors detect the plurality of portions of temperatures, the temperature of entire imaging element can be detected accurately particularly in case the imaging element has a wide area.

The invention described in claim 9 is the imaging device described in any one of claims 1 to claim 8, characterized in that the wirings of the imaging element and signal processing chip are connected electrically by bump electrodes.

According to the invention described in claim 9, since the imaging element and the signal processing chip can be connected without using wires, the wiring space can be minimized.

The invention described in claim 10 is the imaging device described in any one of claims 1 to claim 9, characterized in that the plurality of wiring holes to lace the wires are formed respectively at peripheries of edge sections of the imaging element and the signal processing chip.

According to the invention described in claim 10, by lacing the wires of the imaging element and the signal processing chip through the wiring holes, the part of the wire can be stowed in the components of the imaging device.

### EFFECTS OF THE INVENTION

According to the invention described in claim 1, the manufacturing cost of the imaging device is reduced and the imaging device can be minimized as a whole, and the temperature of the imaging area can be detected accurately.

According to the invention described in claim 2, precise temperature compensation for the temperature characteristic of the imaging element is possible.

According to the invention described in claim 3, in the imaging device including a linear log sensor, temperature compensation for the temperature characteristic of the linear log sensor is possible. According to the invention described in claim 4, by providing the imaging element capable of switching between the plurality of linear conversion characteristics (different inclination), the fluctuation of incline of linear conversion character caused by change of the temperature and the fluctuation of the changeover point can be compensated.

According to the invention described in claim 5, by detecting the temperature of the imaging area accurately, more precise temperature compensation for the temperature characteristic of the imaging element is possible.

According to the invention described in claim 6, since the temperature of the most desirable area to be measured within the imaging area is detected by the temperature sensor, effective temperature compensation becomes possible.

According to the invention described in claim 7, since the temperature sensor is provided in the imaging area of the imaging element, accurate temperature detection can be realized without temperature detection being varied.

According to the invention described in claim 8, since the plurality of temperature sensors detect the temperatures of entire imaging element, precise temperature compensation for the temperature characteristic of the imaging element is possible.

According to the invention described in claim 9, since the wiring space can be minimized the imaging device can be minimized.

According to the invention described in claim 10, by stowing a part of the wire in the component of the imaging device, the imaging device can be minimized.

### BRIEF DESCRIPTION OF THE DRAWINGS

FIG. 1 is a cross-section view showing a configuration of an imaging device related to a first embodiment of the present invention.

FIG. 2 is a plane view showing a configuration of an imaging device related to a first embodiment of the present invention.

FIG. 3 is a plane view showing another exemplary configuration of an imaging device related to a first embodiment of the present invention.

FIG. 4 is a block diagram showing a functional configuration of an imaging device related to a first embodiment of the present invention.

FIG. 5 is a block diagram showing a configuration of an imaging element related to a first embodiment of the present invention.

FIG. 6 is a circuit diagram showing a configuration of pixels which an imaging element related to a first embodiment of the present invention provides.

FIG. 7 is a time chart showing an operation of pixels which an imaging element related to a first embodiment of the present invention provides.

FIG. 8 is a graph showing output signals of an imaging element related to a first embodiment of the present invention provides.

FIG. 9 is a cross-sectional view showing a configuration of an imaging device related to a second embodiment of the present invention provides.

### DESCRIPTION OF THE SYMBOLS

1. imaging device
2. housing
3. lens
4. substrate
5. imaging element
6. signal processing chip
7. micro lens array
8. temperature sensor
9. electrode pad
10. electrode pad
11. wire
12. electrode pad
13. system control section
14. lens unit
15. control section
16. signal processing section
17. timing creation section
18. power line
19. vertical scanning circuit
20. horizontal scanning circuit
21. compensating circuit
32. wiring opening
33. wiring opening
34. bump electrode
35. bump electrode
36. adhering layer
37. adhering layer

### PREFERRED EMBODIMENT OF THE INVENTION

### First Embodiment

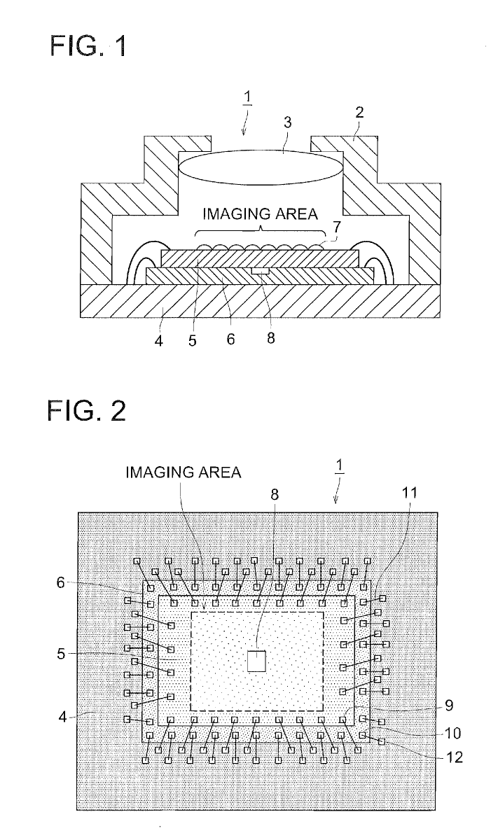

A first embodiment of the present invention will be described with reference to FIG. 1 to FIG. 8.

As FIG. 1 shows, an imaging device 1 is provided with a housing 2 and in a vicinity of a center section of one side surface of the housing 2, a lens 3 to condense image light of an object at a prescribed Focal point is provided in a way that a light axis of the lens 3 is orthogonal to a light receiving surface of the imaging element 5.

Also, a substrate 4 is provide inside the housing 2, on which a signal processing chip 6 and imaging element 5 are respectively stacked via thin adhesion layers (unillustrated). Meanwhile, for the adhesion layer, a resin having a high thermal conductivity is preferred to be used.

The imaging element 5 to perform photoelectric conversion where reflected light of the object coming through a lens 3 is converted into an electric signal is provided at a back surface of the lens 3. Also, a surface opposed to the lens 3 of the imaging element 5 except for a vicinity of edge section is an imaging area where a micro lens array 7 to improve condensability to the pixels of the imaging element 5 are provided.

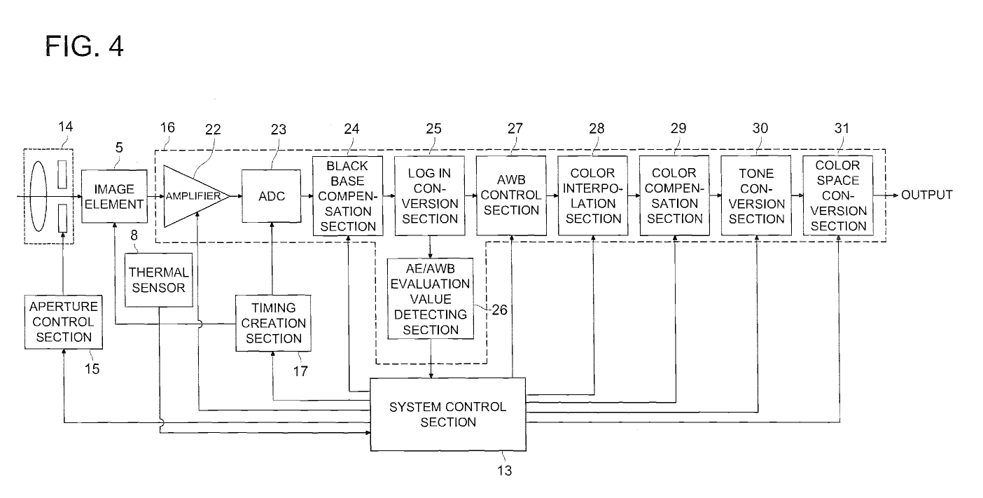

On a signal processing chip 6, circuits such as a system control section 13 and a signal processing section 16 (refer to FIG. 4 for both sections) are provide, and in addition, a temperature sensor 8 representing a temperature detection means is integrated. As FIG. 1 and FIG. 2 show, in a state where the imaging element 5 is stacked on the signal processing chip 6, the temperature sensor 8 is positioned close to the imaging element 5 via a very thin adhesion layer (unillustrated) at a rear surface side near the center of the imaging area. Thereby components of the imaging device 1 can be minimized and a large area where the temperature sensor 8 is in contact with the imaging element 5 via the adhesion layer can be acquired. Meanwhile, as the temperature sensor 8, thermistor having a characteristic where a resistance value is changed according to change of temperature can be used.

Also, as FIG. 1 and FIG. 2 show, in a vicinity of edge of each signal processing chip 6 and the imaging element 5, a plurality of electric pads 9 and 10 are provided which are electrically connected with a plurality of electrode pads 12 provided on a substrate 4 by bonding of respective wires 11.

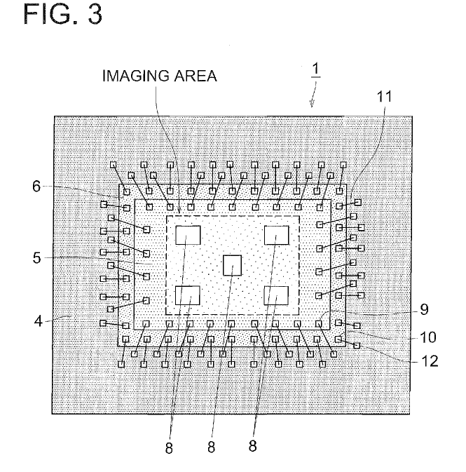

Meanwhile, in the present embodiment, while one temperature sensor 8 is integrate in the vicinity of the center of the signal processing chip 6, as FIG. 3 shows, a plurality of temperature sensors 6 can be integrated with the signal processing chip 6 in an area corresponding to the imaging area of the imaging element 5. By this configuration, even in case the imaging area of the imaging element 5 is large, an accuracy of temperature detection in the imaging area can be improved by detecting the temperature of each area through a plurality of temperature sensors 8.

Next, the functional configuration of the imaging device 1 related to the present invention is shown in FIG. 4.

The imaging device 1 is provided with a system control section 13. The system control section 13 is configured with CPU (Central processing Unit), RAN (Random Access Memory) configured with a rewritable semi-conductor element and ROM (Read Only Memory) configured with a non-volatile semi-conductor memory.

Also, to the system control section 13, each component of image apparatus is connected. The system control section 13 uploads a processing program to the RAM and executes the processing program by the CPU to drive and control each component.

As FIG. 4 shows, to the system control section 13, a lens unit 14, an aperture control section 15, imaging element 5, temperature sensor 8, a signal processing 16 and a timing creation section 17 are connected.

The lens unit 14 is configured with a plurality of lenses to form an optical image of an object on an imaging surface of the imaging element 5 and an aperture section to adjust an amount of light condensed by the lenses.

The aperture control section 15 drives and controls the aperture section to adjust the amount of the light to be condensed by the lenses in the lens unit 14. More specifically, based on a control value inputted from the system control section 13, the aperture section is opened just before photographing operation of the imaging element 5, then after a prescribed exposing time has elapsed, the aperture is closed, in addition, while not photographing, the aperture restricts the incident light to the imaging element 5 so as to control the amount of the incident light.

The imaging element 5 converts the incident light having each color element of R, G, and B representing the object optical image into an electric signal and inputs it. In the present embodiment, a linier log sensor, in which a linier area and a log area of an output signal consecutively changes in accordance with the amount of the incident light, is used as the imaging element 5.

Meanwhile, as the imaging element provided in the imaging device of the present embodiment, any imaging elements having the temperature characteristic can be used, and imaging elements not having the linier area or not having log area in the output signal can be used besides the Tinier log sensor.

The imaging element 5 used in the present embodiment will be described as follow.

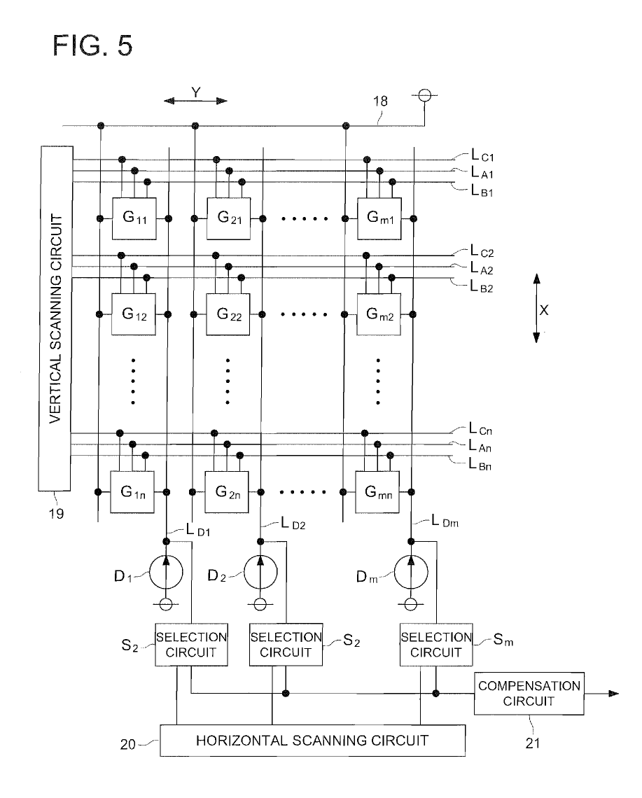

As FIG. 5 shows, the imaging element 5 has a plurality of pixels G₁₁ to Gₘₙ (here, n and m are integer numbers more than 1) arranged in a matrix.

Each pixel G₁₁ to Gₘₙ carries out photoelectric conversions for the incident light to output the electric signals. Converting operation of the electric signal of these pixels G₁₁ to Gₘₙ can be changed over in accordance with the amount of the incident light. Specifically it can changes between linier conversion where the incident light is linearly converted into electric signal and log conversion where the incident light is converted into the electric signal logarithmically. Meanwhile, in the present embodiment, liner conversion or log conversion where the incident light is converted into the electric signal means that a time integration value of the amount of the light is converted into an electric signal which changes linearly or changes logarithmically.

At the lens unit 14 side of the pixels G₁₁ to Gₘₙ, one of filters Red, Green or Blue are disposed (unillustrated). Also, to the pixels G₁₁ to Gₘₙ as FIG. 5 shows, the power line 18 and the signal applying lines L_{A1} to L_{An}, L_{B1} to L_{Bn}, and L_{C1} to L_{Cn}, and the signal read-out lines L_{D1} to L_{Dm} are connected. Meanwhile, to the pixels G₁₁ to Gₘₙ, lines such as clock lines and bias supply lines are connected, however illustrations are omitted in FIG. 5.

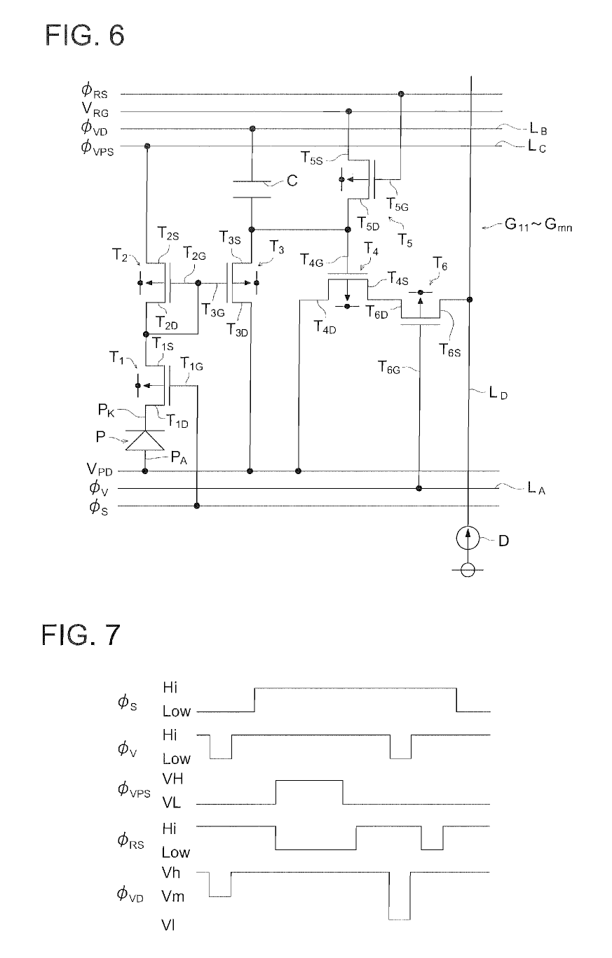

The signal applying lines L_{A1} to L_{An}, L_{B1} to L_{Bn}, and L_{C1} to L_{Cn}, apply signals φᵥ, φ_{VD}, φ_{VPS} and φ_{VPS} (refer to FIG. 6 and FIG. 7). To the signal applying lines L_{A1} to L_{An}, L_{B1} to L_{Bn}, and L_{C1} to L_{Cn}, a vertical scanning line 19 is connected. This vertical scanning line 19 applies signals to the signal applying line L_{A1} to L_{An}, L_{B1} to L_{Bn}, and L_{C1} to L_{Cn}, based on a timing signal creation section 17 (Refer to FIG. 1) and subsequently shifts the objective signal apply lines L_{A1} to L_{An}, L_{B1} to L_{Bn}, and L_{C1} to L_{Cn}, in a X direction.

To the signal read-out lines L_{D1} to L_{Dm}, output signals created by the pixels G₁₁ to Gₘₙ are outputted. To the signal read-out lines L_{D1} to L_{Dm}, constant current power sources D₁ to Dₘ and selection circuits S₁ to Sₘ are connected. Also, at an end of each constant current power source D₁ to Dₘ (an end at lower side in the figure), the direct current voltage V_{PS} is applied.

Selection circuits S₁ to Sₘ sample and hold noise signals given by the pixels G₁₁ to Gₘₙ via each of signal read-out lines L_{D1} to L_{Dm} and electric signals when photographing. To these selection circuit S₁ to Sₘ, a horizontal scanning circuit 20 and a compensation circuit 21 are connected. The horizontal scanning circuit 20 subsequently shifts the selection circuits S₁ to Sₘ in a Y direction to sample and hold the electric signals and to send them to the compensation circuit 21. Also, the compensation circuit 21 eliminates the noise signals from the electric signals based on the noise signals transmitted from the selection circuit S₁ to Sₘ and the electric signal at photographing.

Meanwhile, as the selection circuit S₁ to Sₘ and compensation circuit 21, the circuits disclosed in Patent Document Tokkai 2001-223948 can be used. Also, in the present embodiment, while only one compensation circuit 21 is described to be provided for all the selection circuits S₁ to Sₘ, the compensation circuits 21 can be provided respectively for each of selection circuits S₁ to Sₘ.

Next, the pixels G₁₁ to Gₘₙ having the imaging element 5 will be described.

As FIG. 6 shows, each of pixels G₁₁ to Gₘₙ provide a photo diode P, transistors T₁ to T₆ and a capacitor C. Meanwhile, the transistors T₁ to T₆ are P channel MOS transistors.

It is configured that the photo diode P is not exposed by light coming through the lens unit 14. To an anode P_{A} of the photo diode P, a direct current V_{PD} is applied and to a cathode P_{K} a drain T_{1D} of the transistor T₁ is connected.

To a gate T_{1G} of the transistor T₁, a signal φₛ to be inputted, and to a source T_{1S}, a gate T_{2G} of the transistor T₂ and a drain T_{2D} are connected.

To the source T_{2S} of the transistor T2, the signal applying line L_{C} (corresponding to L_{C1} to L_{Cn} in FIG. 5) is connected so that a signal φ_{VPS} is inputted from the signal applying lines L_{C}. Here, as FIG. 7 shows, the signal P_{VSP} is a binary electric signal and specifically, when the amount of the incident light exceeds a prescribed amount of incident light th, it becomes two values i.e. a voltage value VL to operate the transistor T₂ within a sub-threshold area and a voltage value VH which causes the transistor T₂ conductive.

Also, the source T₁₅ of the transistor T₁, the gate T_{3G} of the transistor T₃ is connected.

To the drain T_{3D} of the transistor T₃, a direct current voltage V_{PD} is to be applied. Also, The source T_{3S} of the transistor T₃ an end of capacitor C, the drain T_{5D} of the transistor T₅ and the gate T_{4G} of the transistor T₄ are connected.

To the other end of the capacitor C, the signal applying line L_{B} (corresponding to L_{B1} to L_{Bn} in FIG. 5) is connected in a way that the signal φ_{VD} is applied from the signal applying line L_{B}. Here, as FIG. 7 shows, the signal φ_{VD} is a three-value electric signal, specifically, it becomes a voltage value Vh when the capacitor C performs integral action, a voltage value Vm when the electric signal converted by photoelectric conversion is read out, and a voltage value V1 when the noise signal is read out.

To the source T_{5S} of the transistor T₅, a direct current voltage V_{RG} is inputted and to the gate T_{5G}, the signal φ_{RS} is inputted.

To the drain T_{4D} of the transistor T₄, a direct current value V_{PD} is applied in the same manner as drain T_{3D} of the transistor T₃, and to the source T_{4S}, the drain T_{6D} of the transistor T₆ is connected.

To the source T_{6S} of the transistor T₆, the signal read-out line L_{D} (corresponding to L_{D1} to L_{Dn} in FIG. 5) is connected, and to the gate T_{6G}, the signal φ_{V} from the signal read-out line L_{A} (corresponding to L_{A1} to L_{An} in FIG. 5) is to be inputted.

With the above circuit structure, each of pixels G₁₁ to Gₘₙ is to perform the following reset operation.

First, as FIG. 7 shows, the vertical scanning circuit 19 performs reset operation of the pixels G₁₁ to Gₘₙ.

Specifically, in a state where the signal φ_{S} is low, the signal φ_{V} is high, the signal φ_{VPS} is VL, the signal φ_{RS} is high, and the signal φVD is Vh, the vertical scanning circuit 19 applies the plus signal φ_{V} and the plus signal φ_{VD} having the voltage value Vₘ to the pixels G₁₁ to Gₘₙ so as to turn off the transistor T₁ by making the signal φ_{S} high after the electric signal is outputted to the signal read line L_{D}.

Next, by the vertical scanning circuit 19 to make the signal φ_{VPS} “VH”, negative charge accumulated in the gate T_{2G} and the drain T_{2D} of the transistor T₂ and the gate T_{3G} of the transistor T₃ is quickly recombined. Also, by the vertical scanning circuit 19 to make the signal φ_{RS} “Low” and by tuning on the transistor T₅, a voltage of connection node between the capacitor C and the gate T_{4G} of the transistor T₄ is initialized.

Next, by the vertical scanning circuit 19 to make the signal φ_{VPS} “VL”, after returning a potential state of the transistor T₂ to an original state, the signal φ_{RS} is made “Hi” to turn off the transistor T₅.

Next, the capacitor perform integral action. Thereby, the voltage of connection node between the capacitor C and the gate T_{4G} of the transistor T₄ accords with the gate voltage of the transistor T₄ which has been reset.

Next, by the vertical scanning circuit 19 to apply the plus signal φ_{V} to the gate T_{5G} of the transistor T₆, the transistor T₆ is turned on and the plus signal φ_{VD} of the voltage value V1 is applied to the capacitor C. When this occurs, since the transistor T₄ operates as a source follower type MOS transistor, the noise signal appears as the electric signal on the signal read-out lines L_{D}.

And then, the vertical scanning circuit 19 applies the plus signal φ_{RS} to the gate T_{5G} of the transistor T₅, so as to reset the voltage of the connection node between the capacitor C and the gate T_{4G} of the transistor T₄, thereafter signal φ_{S} is made “Low” to turn on the transistor T₁. Thereby reset action is completed and the pixels G₁₁ to Gₘₙ become a stat of photographing ready.

Also, the pixels G₁₁ to Gₘₙ are to perform the following photographing operation.

When an optical charge in accordance with the amount of the incident light from the photo diode P flows into the transistor T₂, the optical charge is accumulated in the gate T_{2G} of the transistor T₂.

Here, in case a brightness of the object is low and the amount of the incident light in respect to the photo diode P is less than the prescribed amount of incident light th, the transistor T₂ is in a state of cat-off, thus a voltage in accordance with the amount of the optical charge accumulated in the gate T_{2G} of the transistor T₂ appears at the gate T_{2G}. Thus at the gate T_{3G} of the transistor T₃, a voltage which is a result of converting the incident light linearly appears.

Contrarily, in case the brightness of the object is high and the amount of the incident light in respect to the photo diode P is lager than the prescribed amount of incident light th, the transistor T₂ operates in the sub-threshold area. Thus at the gate T_{3G} of the transistor T₃, a voltage which is a result of converting the incident light of the photo diode through natural logarithmical conversion appears.

Meanwhile, in the present invention, a value of the prescribed value is equal between the pixels G₁₁ to Gₘₙ.

When the voltage appears at the gate T_{3G} of the transistor T₃, an electric current from the capacitor C to the drain T_{3D} of the transistor T₃ is amplified in accordance with the amount of the voltage. Thus at the gate T_{4G} of transistor T₄, a voltage which is a result of converting the incident light of the photo diode P through linier conversion or logarithmical conversion appears.

Next, the vertical scanning circuit 19 makes the voltage value of the signal φ_{VD} to be Vm and the signal φ_{V} “Low”. Thereby a source current in accordance with a gate voltage of the transistor T₄ flows to the signal read-out line L_{D} via the transistor T₆. When this occurs, since the transistor T₄ operates as a source follower type MOS transistor, an electric signal at photographing appears on the signal read-out line L_{D} as a voltage signal. Here the signal value of the electric signal outputted via the transistors T₄ and T₆ is a proportional value to the gate voltage of the transistor T₄, thus the signal value becomes a value which is a result of converting the incident light of the photo diode P through linier conversion or logarithmical conversion.

Then the vertical scanning circuit 19 causes the voltage value of the signal Ø_{VD} to become Vₕ and the signal Ø_{V} to become “Hi” so as to complete photographing operation.

In the above operation, as the voltage value VL of the signal Ø_{VPS} becomes low, and a difference between the voltage value VH of the signal Ø_{VPS} at reset and the voltage value VL becomes large, a potential difference between the gate and source of the transistor T₂ becomes large and a proportion of the brightness of the object where the transistor T₂ operates in a cut off state becomes large. Therefore, as the voltage value VL becomes lower, the proportion of the brightness of the object to be linearly converted becomes large, and as the voltage value VL becomes higher, the proportion of the brightness of the object to be logarithmically converted becomes large. As above, in the output signal of the imaging element 5 of the present embodiment, the linier domain and log domain change continuously.

By changing the voltage value VL of the signal applied to the

pixels G₁₁ to Gₘₙ of the imaging element to operate in such manner, a dynamic range can be changed. Namely, by the system control section 13 to change the voltage value VL, a flexion point, where linier conversion operation of the pixels G₁₁ to Gₘₙ changes to log conversion operation, can be changed.

Meanwhile, in the present embodiment, by changing the voltage value VL of the signal Ø_{VPS} at photographing, linier conversion operation changes into log conversion operation, however, the flexion point in between linier conversion operation and log conversion operation can be changed by changing the voltage value VH of the signal Ø_{VPS}.

Also, in the present embodiment, the imaging element 5 provides RGB filter for each pixel, however, it can provide other color filters such as cyan, magenta and yellow.

Getting back to FIG. 4, the temperature sensor 8 detects a temperature of the imaging area in the imaging element 5, and transfers the detected result to system control section 13.

The signal processing section 16 is configured with an amplifier 22, an AD converter (ADC) 23, a black base compensation section 24, a LogLin conversion section 25, an AE/AWB evaluation value detection section 26, an AWB control section 27, a color complement section 28, a color compensation section 29, a gradation conversion section 30, and a color space conversion section 31.

Among them, the amplifier 22 amplifies the electric signal outputted from the imaging element 5 to a prescribed level so as to compensate lack of level of the photographed image.

Also, the AD converter 23 converts a signal amplified by the amplifier 22 from an analogue signal to a digital signal.

Also, the black basis compensation section 24 compensates a black level representing a lowest brightness value to be a standard value. Namely, due to a variation of the imaging element 5, the black levels differ. Thus black basis compensation is performed by subtracting a signal level representing basis of black level in respect to signal levels of each of RGB signals outputted from the AD converter.

Also, the LogLin conversion section 25 changes the electric signal, created by log conversion operation among the output signals of the imaging element 5, into a state where the signal is linearly converted from the incident light. Namely, the log domain of an output signal having the linier domain and the log domain is made the linear domain so that the output signal becomes an electric signal which changes linearly throughout an entire signal. Thereby, compared to an output signal including both linier domain and log domain, signal processing such as AWB can be performed readily. Meanwhile, in the present embodiment the LogLin conversion section 25 is configured to use a look-up table however, it can be configured to calculate every time the temperature changes.

Also, AE/AWB evaluation value detection section 26 detects each evaluation value from the electric signal linierazed by the LOGLin conversion section 25 so as to carry out automatic exposure control (AE) and automatic white balance (AWB).

Also, by calculating a correction coefficient from the electric signal after black basis compensation, the AWB control section 27 adjusts a level ratio (R/G and B/G) of each color component R, G and B of the photographed image so as to display the white color correctly.

Also, since the only one signal is obtained amount elementary colors in the pixels of the imaging element 5, the color complement section 28 carries out color complementing processing where for each pixel, components of missing colors are complemented from peripheral pixels so that values of color components of R, G and B for each pixel can be obtained.

Also, the color compensation section 29 compensates color components value for each pixel of image data inputted from the color complement section 28 to create an imaged where color of each pixel is adjusted.

Also, the graduation conversion section 30 carries out gamma compensation processing where in order to reproduce an image correctly, given that gamma is one from input of the image to a final output, a response characteristic of graduation of the image is compensated to be an optimal curve in accordance with a gamma value of the imaging device 1 so as to realize an ideal graduation reproduction characteristic.

Also, the color space conversion section 31 converts the color space from RGB to YCbCr. YCbCr is a managing method of color space where colors are expressed by the brightness signal (Y) and two chromaticity i.e. a color-difference signal (Cb) and a color-difference signal (cr) of red, and by converting the color space into YCbCr data, compression of data having only the color-difference signals becomes easy.

Next the timing creation section 17 controls photographing operation (accumulation of charge based on exposure and reading out of accumulated charge) of the imaging element 5. Namely, the timing creation section 17 creates timing pulses (a pixel drive signal, a horizontal synchronizing signal, a vertical synchronizing signal, a horizontal scanning circuit drive signal, and a vertical scanning circuit drive signal) to output them to imaging element 5. Also, the timing creation section 17 creates a timing signal for AD conversion.

The system control section 13 compensates a variation of the output signals of the imaging element 5 caused by a variation of temperature in the imaging area based on a detection result of temperature in the imaging area of imaging element 5 transmitted from the temperature sensor 8.

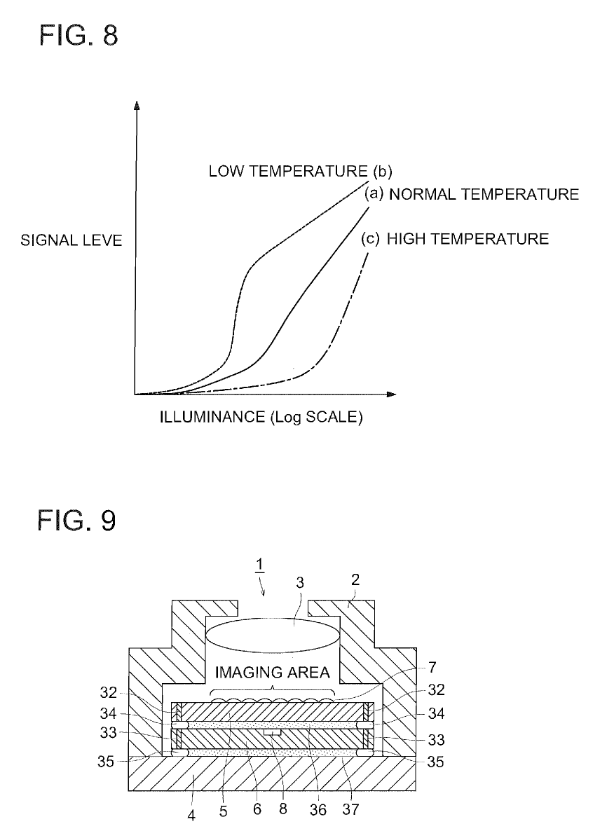

The temperature characteristic of the imaging element 5 varies with configurations of the circuits. FIG. 8 shows exemplary output signals of the image element 5 in various temperatures in the imaging area. A graph (a) in FIG. 8 indicates an output signal in a normal temperature. In FIG. 8, where a horizontal axis of FIG. 8 has a log scale, graphs show that the output signals of the log domain presenting a high brightness domain proportionally change. Also, a graph (b) shows an output signal at a low temperature. Compared with the graph (a), an inclination in the log domain is gentle and rising in linier domain is steep. Also, in conjunction with this, the flexion point representing a boundary point between the log domain and the linier domain is also changed. On the other hand, graph (c) shows an output signal at high temperature and compared with the graph (a), the inclination in the log domain is steep and rising in the linier area is gentle. Also, in conjunction with this, the flexion point is changed.

Based on such temperature characteristic of the imaging element 5, the system control section 13 compensates the variation of the output signal from the imaging element 5 by a prescribed calculation of the output signal after the temperature in the imaging area has changed.

More specifically, the system control section 13 in the present invention compensates the variation of the output signal by adding or subtracting a prescribed correction value, or multiplying or dividing by a prescribed correction coefficient in respect to the output signal after linearization in the look-up table provided by the LogLin conversion section 25. These correction value or correction coefficient can be obtained by measuring an output signal in a prescribed temperature. Meanwhile, the similar compensation can be carried out for the output signal in the log domain before conversion using the look-up table.

Also, as compensation of output signal of the imaging element 5 by the system control section 13, besides compensation carried out when the signal in the log domain is linearized, compensation wherein the output signal in linier domain is compensated by calculation using the correction coefficient or correction value, or compensation by change of the flexion point are possible so that the change of temperature in the imaging area does not affect the characteristic of the output signal of the imaging element 5.

Next, an operation of the imaging device 1 of the present embodiment will be described.

When the power source of the imaging device 1 is turned on, the temperature sensor 8 detects the temperature in the imaging area and transmits it to the system control section 13.

Here, in the imaging device 1 related to the present embodiment, by stacking the signal processing chip 6 in which the temperature sensor 8 is integrated with the imaging element 5, the components of the imaging device 1 can be minimized and the area where the temperature sensor 8 is in contact with the imaging element 5 via the adhesion layer can be widened.

Meanwhile, in the present embodiment, while one temperature sensor 8 is integrated in the vicinity of center of the signal processing chip 6, as FIG. 3 shows, a plurality of the temperature sensors 8 can be integrated in an area corresponding to the imaging area of the imaging element 5 in the signal processing chip 6. Thereby, even in case the imaging area of imaging element 5 is wide, the accuracy of temperature detection in the imaging area can be improved by detecting the temperature of each area by the plurality of the temperature sensors 8.

Further, as FIG. 3 shows, the imaging element 5 has overlapping portions in the imaging area.

Also, the system control section 13 compensates the variation of output signals of the imaging element 5 caused by change of the temperature in the imaging area based on a temperature detection result in the imaging area of the imaging element 5 transmitted from the temperature sensor 8.

In the present embodiment, compensation is carried out for the output signal after linearizing by the look-up table which the LogLin conversion section 25 provides, by adding or subtracting the prescribed correction value, or by multiplying or dividing the prescribed correction coefficient in accordance with the change of the temperature so that an error of the output signal caused by the change of the temperature does not occur. Meanwhile, the same compensation can be carried out for the output signal in the log domain before conversion by the look-up table is carried out.

Here, in case the plurality of the sensors 8 are used, control of the LogLin conversion section 25 can be carried out using an average value of the temperatures detected by each temperature sensor 8. Also, in case the imaging are is wide, and the temperature difference between the temperatures detected by respective temperature sensors 8 exceed a prescribed value, compensation can be carried out for the respective electric signals which is photographed in the respective imaging areas corresponding to respective temperature sensors based on the respective temperatures.

Next, when the imaging element 5 starts imaging operation, charges converted by photoelectric conversion in the pixels G11 to Gmn is scanned in accordance with a timing signal given by the timing creation section 17, and in case the amount of the incident light is small, the image signal is converted linearly and in case the amount of the incident light is large, the image signal is converted logarithmically to be outputted to the amplifier 22.

Then, when the amplifier 22 amplifies the image signal to a prescribed level, the AD converter 23 converts the amplified electric signal from an analogue signal to a digital signal. Further, the black basis compensation section 24 compensates a black level representing a lowest brightness value to be a standard value.

Further, the LogLin conversion section 25 converts the output signal in the log domain into a state where the incident light is linearly converted.

Next, AE/AWB evaluation value detection section 26 detects an AE evaluation value and an AWB evaluation value from the electric signal linearized by the LogLin conversion section 25. Also the AWB control section 27 carries out AWB processing.

Further the color supplement section 28 carries out color supplementing processing, and then the color compensation section 29 compensates the color component value for each pixel of the image data. Also, when the E/AWE evaluation value detection section 26 carries out gamma compensation processing, the color space conversion section 31 converts the color space from RGB to YCbCr.

As above, according to the present embodiment, by integrating the temperature sensor 8 in the signal processing chip 6, the components of the imaging device can be minimized. Also since processing of the output signal of the imaging element is carried out in the signal processing chip 6, a wiring space can be minimized. Also, by integrating the temperature sensor 8 in the signal processing chip 6, compared with a case where these parts are manufactured as the separate parts and allocated, a production process of the imaging device 1 can be simplified. Also, by stacking the signal processing chip 6 where the imaging element 5 and the temperature sensor 8 are integrated, the components of the imaging device 1 can be minimized and an adjacent area of the temperature sensor 8 and the imaging element 5 can be widely acquired so that accurate detection of the temperature of the imaging element 5 is possible.

In particular, in the imaging device 1 having a linier log sensor which converts the incident light linearly or logarithmically in accordance with an amount of the incident light, the variation caused by change of the temperature can be compensated based on a detection result of the temperature sensor.

Also, since a physical distance between the temperature sensor 8 and the imaging area of the imaging element 5 is short the temperature of the imaging area can be detected accurately by the temperature sensor.

Also, because of the configuration, where the temperature sensor 8 is adjacent to the vicinity of the center of the imaging area of the imaging element 5, the temperature of the most desired area to be measured among the imaging area of the imaging element 5 can be detected.

Also, in case a plurality of temperature sensors are used, because a plurality of temperatures of portions of the imaging element 5 can be detected, the temperature of entire image element 5 can be detected accurately particularly for the imaging element 5 having a large area.

Meanwhile, in the present embodiment, as the imaging element 5, while a linier sensor of which output signal has a log domain and a linier domain, is used as the imaging element 5, the imaging element of the present invention can be any imaging element as far as it has temperature characteristic. In case sensors except for linier log sensor are uses as the imaging element, by performing calculation for the output signal of the imaging element using a prescribed correction value or correction coefficient in accordance with change of temperature, the variation of output signal caused by change of the temperature can be compensated. Also, in an imaging device having an imaging element capable of changing a plurality of linear conversion characteristics (having different inclination) in accordance with the amount of the incident light, fluctuation of the inclination of the linear conversion characteristics and fluctuation of a changeover point can be compensated.

### Second Embodiment

A second embodiment of the present invention will be described with reference to FIG. 9. Meanwhile, the same portions as that in the first embodiment are denoted by the same symbols and the description thereof is omitted, thus configurations and operations different from that in the first embodiment will be described.

Aspects where the imaging device 1 is provided with a housing 2, a lens 3, a substrate 4, an imaging element 5 and a signal processing chip 6, and a temperature sensor 8 is integrated in the signal processing chip 6 are the same as that of the first embodiment.

Here, as FIG. 9 shows, at a vicinity of an edge of the imaging element 5 of the present embodiment, a plurality of holes 32 for wiring to lace wires connected with electrode pads 9 are formed. Also, at a vicinity of an edge of the signal processing chip 6, a plurality of holes 33 to lace wires connected to electrode pads 10 are formed.

Also, on a rear surface side of the imaging element 5, there are formed bump electrodes 34 made of solder to electrically connect the wires with the electrode pads 10 of the signal processing chip 6, and on a rear surface side of the signal processing chip 6, there are formed bump electrodes 35 made of solder to electrically connect the wires with the electrode pads 12 of the substrate 4.

Also, the imaging element 5 and the signal processing chip 6 in a stacked state are adhered by very thin adhesion layers 36 and 37.

Meanwhile, a functional configuration of imaging device 1 is the same as that of the first embodiment.

Next, operation of the imaging device 1 will be described.

In the imaging device 1 related to the present embodiment, the imaging element 5 and the signal processing chip 6 are stacked, thereafter the wires connected to the electrode pad 9 of the imaging element 5 of the imaging element 5 are laced through wiring holes 32 to be connected electrically to the electrode pads 10 of the signal processing chip 6 by bump electrodes 34. Also, the wires connected to the electrode pads 10 are laced through wiring holes 33 to be connected electrically to the electrode pads 12 of the substrate 4 by bump electrodes 35. Thereby, the wires of the imaging element 5 and the signal processing chip 6 are connected electrically. Meanwhile, the imaging element 5 and the signal processing chip 6 are adhered by the adhesion layers 36 and 37.

As above, according to the present embodiment, since the imaging element 5 and the signal processing chip 6 can be electrically connected without using the wires, a wiring space can be minimized.

Also, by lacing the wires of imaging element 5 and the signal processing chip 6 through the wiring holes 32 and 33 respectively, parts of the wires can be stowed in the components of the imaging device 1.

As described above, according to the imaging device of the present invention, the manufacturing cost is reduced and the entire imaging device can be minimized. Also, by compensating the output signal by accurately detecting the temperature of the imaging area, precise temperature compensation in respect to the temperature characteristic of the imaging element is possible.

Also, in case the linear log sensor is used as the imaging element, temperature compensation for the temperature characteristic of the linear log sensor is possible.

Further, by detecting the temperature of the imaging area accurately, more precise temperature compensation for the temperature characteristic of the imaging element can be performed.

Furthermore, by detecting the temperature of the most desirable portion of the imaging area to be measured, effective temperature compensation can be performed.

In addition, by accurately detecting the temperature of the entire imaging element through the plurality of the temperature sensors, more precise temperature compensation can be performed in respect to the temperature characteristic of the imaging element.

Moreover, the wiring space can be minimized by the bump electrode and the imaging device can be minimized. Also by the wiring hole, the part of the wire can be stowed in the components of the imaging device, and the imaging device can be minimized.

1. An imaging device, comprising:
an imaging element to convert incident light into an electric signal;
a signal processing chip mounted by being stacked with the imaging element; and
a temperature sensor integrated in the signal processing chip close to the imaging element in a state where the imaging element and the signal processing chip are stacked.

2. The imaging device of claim 1, further comprising a control section to compensate a variation of an output signal of the imaging element caused by a variation of temperature based on a detected result of the temperature sensor.

3. The imaging device of claim 1, wherein the imaging element includes a plurality of pixels capable of switching between linear conversion operation which converts the incident light into the electric signal linearly and log conversion operation which converts the incident light into the electric signal logarithmically in accordance with an amount of the incident light.

4. The imaging device of claim 1, wherein the imaging element, capable of changing between a plurality of linear conversion characteristics in accordance with the amount of the incident light, can compensate a fluctuation of inclination of the linear conversion characteristic caused by a change of temperature and a fluctuation of a changeover point.

5. The imaging device of claim 1, wherein the temperature sensor is integrated close to a rear surface side of an imaging area of the imaging element in the state where the imaging element and the signal processing chip are stacked.

6. The imaging device of claim 1, wherein the temperature sensor is integrated close to a vicinity of a center of the imaging area of the imaging element in the state where the imaging element and the signal processing chip are stacked.

7. The imaging device of claim 1, wherein the temperature sensor is provided in an area corresponding to the imaging area of the imaging element.

8. The imaging device of claim 1, wherein a plurality of the temperature sensors are integrated in the signal processing chip.

9. The imaging device of claim 1, wherein the imaging element and the signal processing chip are electrically connected via bump electrodes.

10. The imaging device of any claim 1, wherein a plurality of wiring holes to lace wires are formed respectively at peripheries of edge sections of the imaging element and the signal processing chip.
